(19) United States
(12) Patent Application Publication
(10) Pub. No.: US 2003/0226687 A1
(43) Pub. Date: Dec. 11, 2003

(54) Method of manufacturing printed wiring board and printed wiring board obtained by the manufacturing method

(76) Inventors: Tatsuo Kataoka, Ageo-shi (JP); Tatsuya Aoki, Ageo-shi (JP); Yasunori Matsumura, Ageo-shi (JP)

Correspondence Address: ROTHWELL, FIGG, ERNST & MANBECK, P.C., 1425 K STREET, N.W., SUITE 800, WASHINGTON, DC, 20005, US

(21) Appl. No.: 10/456,562

(22) Filed: Jun. 9, 2003

(30) Foreign Application Priority Data
Jun. 10, 2002 (JP) P2002-167981

(51) Int. Cl. H05K 1/00; H05K 1/09; G03F 7/20; G03F 7/40

(52) U.S. Cl. 174/250; 430/316; 430/318; 174/257

(57) ABSTRACT

Provided is a method of manufacturing a printed wiring board which keeps a good etching factor of formed circuits, eliminates an etching residue and can effectively prevent the occurrence of surface layer migration.

In the method of manufacturing a printed wiring board which involves using a copper-clad laminate, which is fabricated by bonding together a conductive-circuit formation layer obtained by laminating a copper layer and a dissimilar metal layer other than copper, and an insulating base material so that the copper layer of the conductive-circuit formation layer is exposed to the surface, the above etching of the conductive-circuit formation layer includes a primary etching step of simultaneously dissolving the copper layer and the dissimilar metal layer other than copper which form the conductive-circuit formation layer and a secondary etching step which involves using, after the completion of the primary etching step, a selective etching solution to dissolve only metals which constitute the dissimilar metal layer without dissolving copper.

### BACKGROUND OF THE INVENTION

1. Field of the Invention

The present invention relates to a method of manufacturing a printed wiring board and a printed wiring board obtained by this manufacturing method.

2. Description of the Related Art

There is “migration resistance” as a characteristic which is required as the endurance of a printed wiring board in the case of continuous energizing. This migration resistance refers to resistance to the phenomenon that leak currents flow across conductive-circuits formed in a printed wiring board, bringing about the short state of the circuits.

For the “migration” used in the context of the migration resistance, there are various modes of phenomenon of occurrence depending on the type of printed circuit board. For example, in the case of rigid type printed wiring boards, skeleton materials such as glass cloth and aramid cloth are contained in almost all their insulating material layers and, therefore, the copper component which constitutes plated layers applied to interlayer conducting means such as a through hole is affected by the energizing environment. As a result, the copper component diffuses along the interfaces between the skeleton materials and the resin layers and comes into contact with adjacent circuits, bringing about short circuits. This mode is called internal diffusion migration. Also, there is another mode in which during the energizing across circuits, surface layer currents flow across outer layer circuits and diffuse the copper which constitutes the circuits, thereby forming conducting bridges between the outer layer circuits, with the result that short circuits occur. This mode is called surface layer migration.

On the other hand, in the case of flexible type printed wiring boards, polyimide resins, polyethylene resins, etc. are singly used as insulating base materials and skeleton materials are not used. Therefore, only surface layer migration is apt to occur. Therefore, during energizing across circuits, surface layer currents flow across outer layer circuits and diffuse the component metals of copper, tin, etc. of plated portions which constitute the circuits, thereby forming conducting bridges between outer layer circuits, with the result that short circuits occur.

Among the above-described migration phenomena, in the case of surface layer migration, it might be thought that after the formation of a circuit configuration by etching a copper-clad laminate, surface layer currents are apt to flow due to the presence of metal components still remaining in trace amounts on the surface of the exposed insulating base material where the copper layer is removed by etching, even after etching. FIG. 4 shows the state of completion of circuit formation by usual etching. As indicated by an arrow in this FIG. 4, at the interface of an edge portion of a circuit with an insulating base material, an etching residue of a dissimilar metal layer (hereinafter simply referred to as “an etching residue”) can be observed from the edge portion of the circuit in the direction of inter-circuit gap. It might be thought that this etching residue provides an initiation portion which generates leak currents across formed circuits during the energizing of the circuits. As a result, there are cases where the copper which constitutes the circuits moves in an electrophoretic manner and forms conducting bridges of copper oxide etc. between the circuits, with the result that short circuits occur.

Alternatively, in the case of plating of circuits with tin, solder, etc., it has been thought that due to the presence of an etching residue as described above, the circuit edge configuration after plating obtains projections and depressions and becomes of very poor quality as shown in FIG. 5, thereby greatly impairing the linearity of finished circuits and that simultaneously the component metals used in plating bring about surface layer migration. To cope with such phenomena as described above, various measures such as an improvement in an etching solution and prolongation of etching time have been examined as methods of etching circuits.

However, the present inventors ascertained that the result that the longer the etching time for circuit formation of a copper-clad laminate, the less surface layer migration will become apt to occur, has not been obtained. The cause seems to be as follows.

Even when the above-described etching residue is to be removed by simply prolonging etching time, setting etching time unnecessarily long (which means increasing what is called over-etching time) is impossible from the problem of circuit configuration. That is, circuits of a printed wiring board are used as electric conductors of current and it is necessary to finish these circuits with sections having good accuracy according to product use. In other words, it is necessary to obtain circuits having a good etching factor. In the recent trend toward miniaturization of electronic and electric devices, fine pitch design of the circuits of printed circuit boards built in these devices is also remarkable and in particular the scale-down of signal transmission circuits is striking. Therefore, if the etching factor worsens and circuits are finished with a circuit width smaller than initially designed circuits, a rise in resistance occurs, bringing about a delay in signal transmission. This may give rise to malfunctions of products.

Therefore, it is impossible to set over-etching time at such a level that might worsen the etching factor of the sectional shapes of circuits. In the process of the research by the present inventors it became apparent that even when etching time is prolonged to such a level that might worsen the etching factor of usual circuit configurations, an etching residue as shown in FIG. 4 is not eliminated and hence results which contribute to the prevention of surface layer migration could not be obtained.

In view of the foregoing, even when the problem of surface layer migration can be solved simply by prolonging over-etching time in circuit etching, it is not only impossible to obtain a good etching factor of formed circuit sections, but also impossible to eliminate the etching residue referred to in the present specification. Consequently, as long as this etching residue exists, it is impossible to effectively prevent surface layer migration and hence a manufacturing method which drastically eliminates an etching residue has been desired.

### SUMMARY OF THE INVENTION

Accordingly, the present inventors devoted themselves to research and as a result they hit upon the idea that by adopting a method of manufacturing a printed wiring board as described below, it is possible to keep a good etching factor of formed circuits, eliminate an etching residue of a dissimilar metal layer and effectively prevent the occurrence of surface layer migration. Incidentally, in the present invention, a printed wiring board is a technology that can be applied to all rigid substrates as represented by glass epoxy substrates and CEM3 substrates, flexible printed wiring boards as used in the flexible driving parts of printers etc., and flexible substrates of TAB film etc. used in liquid crystal drivers. Therefore, the concept of a copper-clad laminate is also used in such a way that both rigid substrates and flexible substrates are included in the copper-clad laminate.

The gist of a claim of the invention is as follows: “a method of manufacturing a printed wiring board; comprising the steps of: forming an etching resist layer on a surface of a copper-clad laminate, which is fabricated by bonding together a conductive-circuit formation layer obtained by laminating a copper layer and a dissimilar metal layer other than copper, and an insulating base material so that the copper layer of the conductive-circuit formation layer is exposed to the surface; forming a resist pattern providing a circuit pattern, by exposing and developing the etching resist layer; etching thereafter the conductive-circuit formation layer; and forming a circuit pattern by causing the conductive-circuit formation layer to remain only in a circuit formation portion, by removing the conductive-circuit formation layer in other portions and by exposing an insulating base material portion of the copper-clad laminate; wherein the etching of the conductive-circuit formation layer comprises a primary etching step and a secondary etching step; the primary etching step involving using an etching solution capable of simultaneously dissolving the copper layer and the dissimilar metal layer other than copper which form the conductive-circuit formation layer; and the secondary etching step involving performing, after the completion of the primary etching step, finish removal etching of dissimilar metal components other than copper which remain on the surface of the exposed insulating base material by use of a selective etching solution capable of dissolving only metals other than copper which constitute the dissimilar metal layer.”

To put the gist of the present invention differently in the simplest way, it can be said that the gist of the invention resides in removing metal components remaining in the surface of an insulating resin substrate exposed by performing etching again after ordinary circuit etching. It can be said that the invention has features in the two points that the conductive-circuit formation layer is “a circuit formation layer in which a copper layer and a dissimilar metal layer other than copper are laminated” and that “an etching solution capable of dissolving both copper and dissimilar metals other than copper is used in the primary etching step, whereas a selective etching solution capable of dissolving only the dissimilar metals without dissolving copper is used in the secondary etching step.”

First, “a conductive-circuit formation layer in which a copper layer and a dissimilar metal layer other than copper are laminated” is used in such a manner that, as shown in FIG. 1 as a schematic sectional view of a copper-clad laminate, the dissimilar metal layer is positioned between the base material surface and the copper layer, and in this specification the copper layer and the dissimilar metal layer are together called the conductive-circuit formation layer. However, for convenience of explanation, the copper layer and the dissimilar metal layer will be discriminately used in the descriptions. Such a conductive-circuit formation layer may sometimes be used as a barrier layer to ensure what is called UL heat resistance in rigid type printed wiring boards. And among flexible type printed wiring boards, in what is called a dual-layer flexible printed wiring board in which a conductive-circuit formation layer is formed directly on a flexible base material by omitting a bonding material layer, this conductive-circuit formation layer is inevitably formed.

A process for manufacturing a printed wiring board from a copper-clad laminate which comprises the steps \mathring{1} to \mathring{4} will be briefly described. \mathring{1} The surface conditioning step is carried out to improve the adhesion of an etching resist by cleaning the surface of a conductive-circuit formation layer of a copper-clad laminate (usually, electrodeposited copper foil or rolled copper foil being used) and performing physical polishing or chemical polishing or by the combined use of these two types of polishing (however, this surface conditioning step may sometimes be omitted). \mathring{2} On the surface of the conductive-circuit formation layer of the copper-clad laminate dried after the completion of the surface conditioning step, the formation of an etching resist layer using a dry film, a liquid resist, etc. is performed as the resist application step. \mathring{3} After the formation of the etching resist layer in the resist application step, the exposure and development step is performed by exposing and developing a circuit pattern formed in this etching resist layer so as to cause this etching resist layer to remain only in a circuit-pattern formation portion. \mathring{4} And in the circuit etching step, for the copper-clad laminate for which the exposure and development step has been completed, the conductive-circuit formation layer in a portion where the etching resist does not remain in the surface layer is dissolved and removed by use of an appropriate etching solution, whereby only the conductive-circuit formation layer positioned in a lower part of the etching resist layer which is caused to remain in the circuit pattern is caused to remain as the circuit pattern configuration.

Basically, the above-described general etching process adopted in working a copper-clad laminate in a printed wiring board forms foundations also for the present invention. And technical features of the invention of this patent application reside in the use of the conductive-circuit formation layer comprising the copper layer and the dissimilar metal layer and the circuit etching step described in \mathring{4} above. In the invention, the formation of a circuit pattern is performed by dividing this etching step into a primary etching step and a secondary etching step. That is, the prevention of surface layer migration is effectively performed by dividing the circuit etching step into the primary etching step and the secondary etching step in a case where the conductive-circuit formation layer comprising the copper layer and the dissimilar metal layer is used.

In the conductive-circuit formation layer, copper is used as a minimum required indispensable layer and dissimilar metals other than copper are laminated on this copper layer. It seems possible to form this dissimilar metal layer by using dissimilar metals which permit selective etching with respect to copper so long as these dissimilar metals fulfill functions required as a printed wiring board. At the present stage, however, it is preferable to use nickel and nickel alloys, such as nickel-chromium alloys, nickel-iron alloys, nickel-phosphorus alloys and nickel-cobalt-zinc alloys, as the dissimilar metal layer from the standpoints of very stable adhesion of the conductive-circuit formation layer to the base material, stabile peeling strength and excellent heat resistance stability. These dissimilar metals permit selective etching with respect to copper and hence conform to the object of the invention. That is, the selective etching called herein refers to etching which dissolves only dissimilar metals other than copper without dissolving copper.

This conductive-circuit formation layer can be fabricated by arbitrarily selecting either 1) a method which involves obtaining the conductive-circuit formation layer as a material in foil form which is integral with the copper layer by forming the dissimilar metal layer on the surface of copper foil or 2) a method which involves forming the dissimilar metal layer on the surface of the insulating resin base material and further forming the copper layer on the surface of this dissimilar metal layer, thereby forming the conductive-circuit formation layer directly on the surface of the insulating resin base material.

Formation of the dissimilar metal layer and the copper layer in the above-described method 2) may be formed by the electrolysis process and the electroless process as electrochemical techniques and by a sputtering deposition process (physical thin-film forming processes) or a chemical vapor reaction process. Methods of forming the dissimilar metal layer need not be specially limited.

An arbitrary thickness may be selectively used as the thickness of the copper layer constituting the conductive-circuit formation layer according to the level of the fineness of circuits to be formed and special specification of this thickness is not required. In contrast, it is preferred that the thickness of the dissimilar metal layer be 50 Å to 2 μm. In the case where this dissimilar metal layer is present on a surface having projections and depressions as a nodular-treated surface used for the bonding to the base material of copper foil, the thickness of this dissimilar metal layer is described as a converted value obtained by regarding this surface as a uniform flat surface.

When the thickness of this dissimilar metal layer is more strictly discriminated, the following can be said. In the case of a dual-layer board used when very fine circuits are formed as with a flexible printed wiring board, the thickness of the conductive-circuit formation layer is generally small and in the range of 3 to 12 μm. Usually, the thickness of the dissimilar metal layer in this case is in the range of 30 Å to several hundred Å. What is referred to as “etching residue” herein occurs when the thickness of the dissimilar metal layer is not less than 50 Å. In contrast, in the case of a rigid printed wiring board, the dissimilar metal layer is often used as a barrier layer to ensure heat resistance and thicknesses in the range of 0.1 μm to 3 μm are adopted in such cases. As for the upper limit of the dissimilar metal layer, however, the removal of dissimilar metal components by etching cannot be adequately performed when the dissimilar metal layer becomes too thick and exceeds 2 μm in thickness and the level of an etching residue becomes serious, because the copper layer and the dissimilar metal layer have to be simultaneously removed in the primary etching step. All these things considered, in the present specification the specified thickness of the dissimilar metal layer is 50 Å to 2 μm.

Next, the etching step will be described below. The primary etching step refers to a step in which the copper layer and the dissimilar metal layer which constitute the conductive-circuit formation layer are simultaneously dissolved and removed. Usually, a basic circuit configuration is completed by this etching treatment. Therefore, almost all metal components that constitute the conductive-circuit formation layer are removed in this primary etching step and under ordinary circumstances this permits the use of the product as a printed wiring board.

Because the solution used in this primary etching step is used to simultaneously dissolve the copper layer and dissimilar metal layer which constitute the conductive-circuit formation layer, it is possible to use a cupric chloride solution which is an oxidizing etching solution, a mixed solution of hydrochloric acid and hydrogen peroxide solution, etc.

At the stage when the primary etching step has been completed, on the surface of the insulating base material of a circuit edge portion in the vicinity of an interface with the base material, there occurs an etching residue, which is a remaining portion of unremoved dissimilar metal layer, from the circuit edge portion in the direction of the inter-circuit gap as shown in FIG. 4. This etching residue cannot be removed simply by prolonging the over-etching time of the primary etching step. It might be thought that this phenomenon occurs due to a difference in the tendency toward ionization between copper and metal components constituting the dissimilar metal layer, such as nickel, and an imbalance between an etching solution and a solution supply rate.

The secondary etching step is performed to dissolve only the metal components which constitute the dissimilar metal layer without dissolving copper. In the case where nickel or a nickel alloy is used in the dissimilar metal layer, it follows that a nickel selective etching solution is used which preferentially dissolves nickel in the presence of copper and nickel and which scarcely dissolves copper. By performing such selective etching, only dissimilar metal components remaining as an etching residue are removed without dissolving the copper component of circuits. As a result, the worsening of the etching factor of circuits does not occur any more.

It is preferred that a solution of the basic composition of any one of \mathring{1} a sulfuric acid solution in concentrations from 550 ml/l to 650 ml/l, \mathring{2} a mixed acid solution of sulfuric acid and nitric acid, and \mathring{3} a mixed solution of sulfuric acid and m-nitrobenzenesulfonic acid be used as this nickel selective etching solution. However, additives such as a polymer to increase the uniformity of etching and to control etching can also be added as required. It is also possible to use ENSTRIP 165S etc. made by Meltex Inc.

More desirably, the solution \mathring{1} as a sulfuric acid solution in concentrations from 580 ml/l to 620 ml/l is used to cathodically polarize the copper-clad laminate in this solution and to exfoliate the nickel layer by electrolysis. The reason why the specified concentration of sulfuric acid is 550 ml/l to 650 ml/l is that the etching rate of nickel etc. is low at concentrations below 550 ml/l, causing damage also to the copper layer side. And this is also because at concentrations exceeding 650 ml/l, the etching rate does not increase and the dissolution reactivity of nickel becomes slow. The more desirable concentration range of 580 ml/l to 620 ml/l is a region in which the removal rate and the stability of solution quality are best. For the solutions \mathring{2} and \mathring{3}, there is no limit to concentration etc. and it is necessary only that optimum conditions be set in consideration of the step.

In a printed wiring board which has passed through the secondary etching step as described above, the etching residue which was present at the interface of a circuit edge portion with the insulating base material is not observed any more as shown in FIG. 2. Because of the elimination of this etching residue, the initiation portion which generates leak currents across circuits during the energizing of the formed circuits goes out of existence. As a result, it becomes possible to ensure excellent migration resistance by effectively preventing the occurrence of the migration phenomenon.

Incidentally, to spell out here, the final removal of the etching resist layer after circuit etching in the present specification may be performed after the completion of the two etching steps of the primary and secondary etching steps or between the primary etching step and the secondary etching step. This is because a nickel selective etching solution is used as the etching solution to be used in the secondary etching step, with the result that the dissolution of the copper component of circuits scarcely occurs.

Furthermore, even when circuits formed on a printed wiring board which has passed through the secondary etching step are plated with tin, solder, etc., as shown in FIG. 3, it is possible to keep the linearity of the circuit edge configuration after plating in good condition because of nonexistence of an etching residue. Thus, it becomes possible to effectively prevent a case where the component metals used in plating might cause surface layer migration. In addition, a very beautiful circuit configuration after plating makes it possible to improve the formation yield of fine pitch circuits, thereby resulting in an improvement in productivity.

### BRIEF DESCRIPTION OF THE DRAWINGS

FIGS. 1A and 1B are each a schematic sectional view of a copper-clad laminate;

FIG. 2 is an image of an edge portion of formed circuit observed under a scanning electron microscope;

FIG. 3 is an image of an edge portion of formed circuit after plating observed under a scanning electron microscope;

FIG. 4 is an image of an edge portion of formed circuit observed under a scanning electron microscope (conventional example); and

FIG. 5 is an image of an edge portion of formed circuit after plating observed under a scanning electron microscope (conventional example).

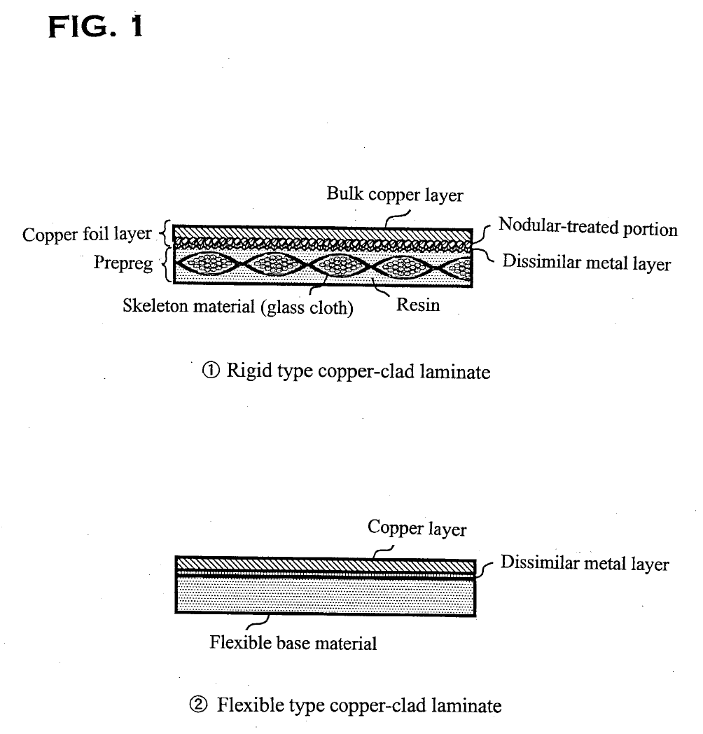

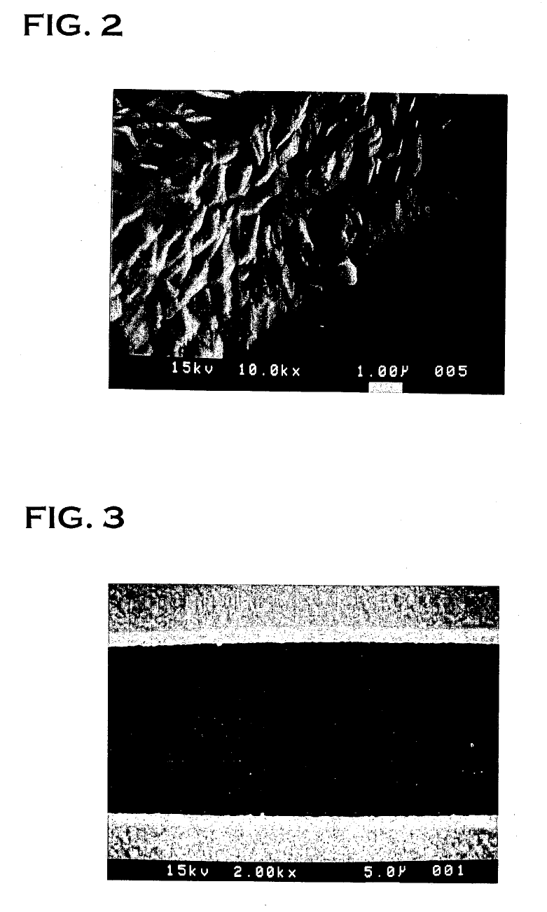

### DETAILED DESCRIPTION OF THE PREFERRED EMBODIMENTS

Printed wiring boards were fabricated on the basis of the above-described invention and a test to evaluate migration resistance was carried out by use of the printed wiring boards. The results of the test will be described below.

### EXAMPLE

In this example, a rigid type printed wiring board was used. The printed wiring board was a double-sided printed wiring board in which circuits were formed on both sides of an FR-4 substrate, and the test to evaluate migration resistance was carried out by use of this double-sided printed wiring board.

First, a copper-clad laminate to be used in the fabrication of a printed wiring board was fabricated. In the fabrication of the copper-clad laminate, 18-μm thick electrodeposited copper foil which has a 0.5-μm thick nickel layer as a dissimilar metal layer on a nodular-treated surface used for the bonding to a base material (hereinafter simply referred to as “electrodeposited copper foil”) and a 100-μm thick FR-4 glass epoxy prepreg were used. What is called a double-sided copper-clad laminate was fabricated by superposing the electrodeposited copper foil on both sides of this prepreg, with the nodular-treated surface of the copper foil opposed to the prepreg, and performing hot press forming.

An etching resist layer was formed on a conductive-circuit formation layer on both sides of the above-described double-sided copper-clad laminate. In the formation of this etching resist layer, a dry film made by Nichigo Alfo Co., Ltd. was used. A conductive-circuit pattern to be formed on this etching resist layer was exposed and developed.

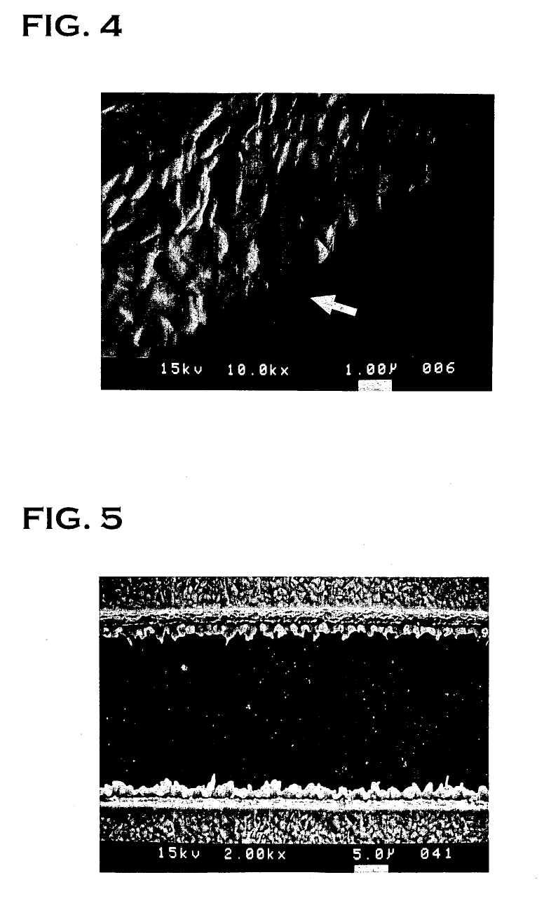

After that, as the primary etching step, the state of a preliminary printed wiring board was obtained by etching the conductive-circuit formation layer in a copper chloride etching solution. When the edge portion of the circuits finished at this stage was observed under a scanning electron microscope, an etching residue similar to that shown in FIG. 4 was recognized. It was ascertained by performing an analysis by an EPMA that this portion is nickel. The etching factor determined from the circuit section at this stage was 1.76.

After the completion of the primary etching step, etching was performed again for 60 seconds in a nickel selective etching solution which does not dissolve copper as the secondary etching step. A sulfuric acid solution obtained by adding special-grade sulfuric acid to ion-exchange water to obtain a concentration of 600 ml/l was used in the nickel selective etching performed this time. Water washing was finally performed. In this manner, as a result of the secondary etching step, no etching residue was recognized when an edge portion of finished circuits was observed under a scanning electron microscope and the etching residue went out of existence. Nickel was not detected in an analysis by an EPMA, either. The etching factor determined from the circuit section at this stage was 1.75 and it is apparent that this value scarcely differs from the value obtained upon completion of the primary etching step in consideration of the existence of measurement errors.

After the completion of the formation of the conductive-circuit as described above, the removal work of the etching resist layer was carried out. This work was carried out by the swelling removal of a hardened etching resist layer in a commercially available alkaline resist removal liquid. A double-sided printed wiring board was obtained by completing this removal work of the etching resist layer.

The conductive-circuit configuration formed on the surface of the above-described double-sided printed wiring board is such that a plurality of test patterns to be used in the test to evaluate migration resistance can be obtained. That is, one test pattern defines 100 linear conductors which are 100 μm in circuit width, 100 μm in inter-circuit width and 10 cm in length. Out of the 100 linear conductors, 50 ones connected to the anode of a power source and 50 ones connected to the cathode of the power source are arranged parallel to each other and alternately to form a comb-shaped circuit configuration. This comb-shaped circuit was used to evaluate migration resistance. With a 1-volt power source kept connected to the conductors of this comb-shaped circuit, the circuit was immersed in a hydrochloric acid solution at a concentration of 10⁻⁶ mol/l, migration was caused to occur. The time which elapses until a short current of 50 mA begins to flow across adjacent linear conductive-circuits was measured. As a result, it took 1253 seconds.

### Comparative Example

In this comparative example, a rigid type printed wiring board was used. The printed wiring board was a double-sided printed wiring board in which circuits were formed on both sides of an FR-4 substrate, and the test to evaluate migration resistance was carried out by use of this double-sided printed wiring board.

More specifically, in the method of fabricating the double-sided printed wiring board according to the comparative example, the secondary etching step in the above example was omitted and other steps were the same as in the above example. To avoid the duplication of descriptions, detailed descriptions are omitted here. And to permit a comparison with the above example, only the result of the evaluation of migration resistance is described.

As with the above example, the conductive-circuit configuration formed on the surface of the double-sided printed wiring board is such that a plurality of test patterns to be used in the test to evaluate migration resistance can be obtained. Because the test pattern and test method of the test to evaluate migration resistance are also the same as with the above example, their descriptions are also omitted here. In the test to evaluate migration resistance, the time which elapses until a short current of 50 mA begins to flow across adjacent linear conductive-circuits was measured. As a result, it took 453 seconds.

As described above, in a printed wiring board obtained through the secondary etching step, which is one of the features of the present invention, an etching residue conventionally present at the interface of a circuit edge portion with the insulating base material is not observed. Because this etching residue goes out of existence, the occurrence of surface layer migration during the energizing of formed circuits is effectively prevented and it becomes possible to ensure excellent migration resistance. Furthermore, even when circuits formed on a printed wiring board which has passed through the secondary etching step are plated with tin, solder, etc., it is possible to keep the linearity of the circuit edge configuration after plating in good condition because of nonexistence of an etching residue. Thus, it becomes possible to effectively prevent a case where the component metals used in plating might cause surface layer migration. In addition, a very beautiful circuit configuration after plating makes it possible to improve the formation yield of fine pitch circuits, thereby resulting in an improvement in productivity.

What is claimed is:

1. A method of manufacturing a printed wiring board; comprising the steps of:
forming an etching resist layer on a surface of a copper-clad laminate, which is fabricated by bonding together a conductive-circuit formation layer obtained by laminating a copper layer and a dissimilar metal layer other than copper, and an insulating base material so that the copper layer of the conductive-circuit formation layer is exposed to the surface;
forming a resist pattern providing a circuit pattern, by exposing and developing the etching resist layer;
etching thereafter the conductive-circuit formation layer; and
forming a circuit pattern by causing the conductive-circuit formation layer to remain only in a circuit formation portion, by removing the conductive-circuit formation layer in other portions and by exposing an insulating base material portion of the copper-clad laminate;
wherein said etching of the conductive-circuit formation layer comprises a primary etching step and a secondary etching step;
said primary etching step involving using an etching solution capable of simultaneously dissolving the copper layer and the dissimilar metal layer other than copper which form the conductive-circuit formation layer; and
said secondary etching step involving performing, after the completion of the primary etching step, finish removal etching of dissimilar metal components other than copper which remain on the surface of the exposed insulating base material by use of a selective etching solution capable of dissolving only metals other than copper which constitute the dissimilar metal layer.

2. The method of manufacturing a printed wiring board according to claim 1, wherein the dissimilar metal layer other than copper which forms the conductive-circuit formation layer is nickel or a nickel alloy and wherein the selective etching solution used in the secondary etching step is any one of the solutions \mathring{1} to \mathring{3} below:
\mathring{1} a sulfuric acid solution in concentrations from 550 ml/l to 650 ml/l
\mathring{2} a mixed acid solution of sulfuric acid and nitric acid
\mathring{3} a mixed solution of sulfuric acid and m-nitrobenzenesulfonic acid

3. A printed wiring board obtained by the manufacturing method according to claim 1 or 2.
